(19) United States
(12) Patent Application Publication
(10) Pub. No.: US 2017/0335451 A1
(43) Pub. Date: Nov. 23, 2017

(54) STATIC THERMAL CHEMICAL VAPOR DEPOSITION WITH LIQUID PRECURSOR

(71) Applicant: SILCOTEK CORP., Bellefonte, PA (US)

(72) Inventors: Nicholas P. DESKEVICH, Hollidaysburg, PA (US); Pierre A. LECLAIR, Pa Furnace, PA (US); David A. SMITH, Bellefonte, PA (US)

(21) Appl. No.: 15/599,019

(22) Filed: May 18, 2017

Related U.S. Application Data
(60) Provisional application No. 62/340,115, filed on May 23, 2016.

(51) Int. Cl. C23C 16/448; C23C 16/32; C23C 16/42; C23C 16/455

(52) U.S. Cl. CPC C23C 16/4485; C23C 16/45563; C23C 16/32; C23C 16/42; C23C 16/4481

(57) ABSTRACT

Static thermal chemical vapor deposition treatment processes and static thermal chemical vapor deposition treatment systems are disclosed. The process includes providing an enclosed chamber configured to produce a material on a surface of an article within the enclosed chamber in response thermal energy being applied to a gaseous precursor, providing a liquid handling system in selective fluid communication with the enclosed chamber, flowing a liquid precursor through the liquid handling system, converting the liquid precursor to the gaseous precursor, and producing the material on the surface of the article in response to the thermal energy being applied to the gaseous precursor within the enclosed chamber. The system includes the enclosed chamber and the liquid handling system.

### PRIORITY

The present application is a non-provisional patent application claiming priority and benefit to U.S. provisional patent application No. 62/340,115, filed May 23, 2016 and titled “STATIC THERMAL CHEMICAL VAPOR DEPOSITION WITH LIQUID PRECURSOR,” which is incorporated by reference in its entirety.

### FIELD OF THE INVENTION

The present invention is directed to static thermal chemical vapor deposition treatment processes and static thermal chemical vapor deposition treatment systems. More particularly, the present invention is directed to treatment processes and systems for using a liquid precursor.

### BACKGROUND OF THE INVENTION

Chemical vapor deposition processes involve the introduction of a precursor fluid which imparts a material or modification of a surface. In thermal chemical vapor deposition, the precursor fluid is introduced at an elevated temperature and a low pressure, facilitating the imparting of the material or the modification of the surface.

Processes involving a liquid precursor fluid are very different from processes involving gaseous fluid precursors. For example, liquid precursor fluids are non-compressible and flow different from gaseous fluid precursors. Characteristics of liquid precursor fluids are also more susceptible to changes in temperature. For example, flow rate of a liquid precursor fluid can be drastically increased due to decreased viscosity corresponding to an increase in temperature. In contrast, viscosity of a gas is increased with an increase in temperature.

Such flow characteristics of liquid precursor fluids can be especially complicated in dealing with a static chamber. In flow-through chambers, liquid fluid precursors convert into a gaseous fluid precursor and are replenished until the process is complete. In a static chamber, there is no replenishment, so an increase or decrease in the flow rate of the liquid precursor can produce undesirable results.

In addition, liquid precursors can require a carrier fluid. The carrier fluid must be compatible with the liquid precursor, such as, by being inert or otherwise not appreciably reactive with the liquid precursor. In circumstances where the carrier fluid is a gas, introduction of the carrier fluid can impact deposition/treatment, for example, by impacting the pressure, by affecting particulate generation, and/or by affecting the ability to penetrate into high aspect ratio configurations.

Treatment processes and treatment systems that improve upon one or more of the above drawbacks would be desirable in the art.

### BRIEF DESCRIPTION OF THE INVENTION

In an embodiment, a static thermal treatment process includes providing an enclosed chamber configured to produce a material on a surface of an article within the enclosed chamber in response thermal energy being applied to a gaseous precursor, providing a liquid handling system in selective fluid communication with the enclosed chamber, flowing a liquid precursor through the liquid handling system, converting the liquid precursor to the gaseous precursor, and producing the material on the surface of the article in response to the thermal energy being applied to the gaseous precursor within the enclosed chamber.

In another embodiment, a static thermal treatment system includes an enclosed chamber configured to produce a material on a surface of an article within the enclosed chamber in response to thermal energy being applied to a gaseous precursor, and a liquid handling system in selective fluid communication with the enclosed chamber. The static thermal treatment system is capable of converting a liquid precursor flowing through the liquid handling system to the gaseous precursor within the chamber. The static thermal treatment system is capable of producing the material on the surface of the article in response to the thermal energy being applied to the gaseous precursor within the enclosed chamber.

In another embodiment, a static thermal treatment process includes providing an enclosed chamber configured to produce a material on a metal or metallic surface of an article within the enclosed chamber in response thermal energy being applied to a gaseous precursor, converting a fluorine-containing liquid precursor to the gaseous precursor, and producing the material on the metal or metallic surface of the article in response to the thermal energy being applied to the gaseous precursor within the enclosed chamber.

Other features and advantages of the present invention will be apparent from the following more detailed description, taken in conjunction with the accompanying drawing which illustrates, by way of example, the principles of the invention.

### BRIEF DESCRIPTION OF THE DRAWINGS

FIG. 1 is a perspective view of a static thermal chemical vapor deposition treatment system, according to an embodiment of the disclosure.

Wherever possible, the same reference numbers will be used throughout the drawings to represent the same parts.

### DETAILED DESCRIPTION OF THE INVENTION

Provided are static thermal chemical vapor deposition treatment processes and static thermal chemical vapor deposition treatment systems. Embodiments of the present disclosure, for example, in comparison to concepts failing to include one or more of the features disclosed herein, permit treatment processes and systems to use a liquid precursor, permit welding and/or assembly of complex configurations prior to treatment, permit direct modification/treatment of metal or metallic materials, permit non-line-of site (three-dimensional) modifications/treatments, permit direct modification/treatment of all exposed surfaces, permit treatment processes to maintain controlled flow over a larger temperature range, permit features not present in flow-through systems (for example having a precise volume of a liquid precursor throughout a reaction and/or permitting complete reaction), and/or permit combinations thereof.

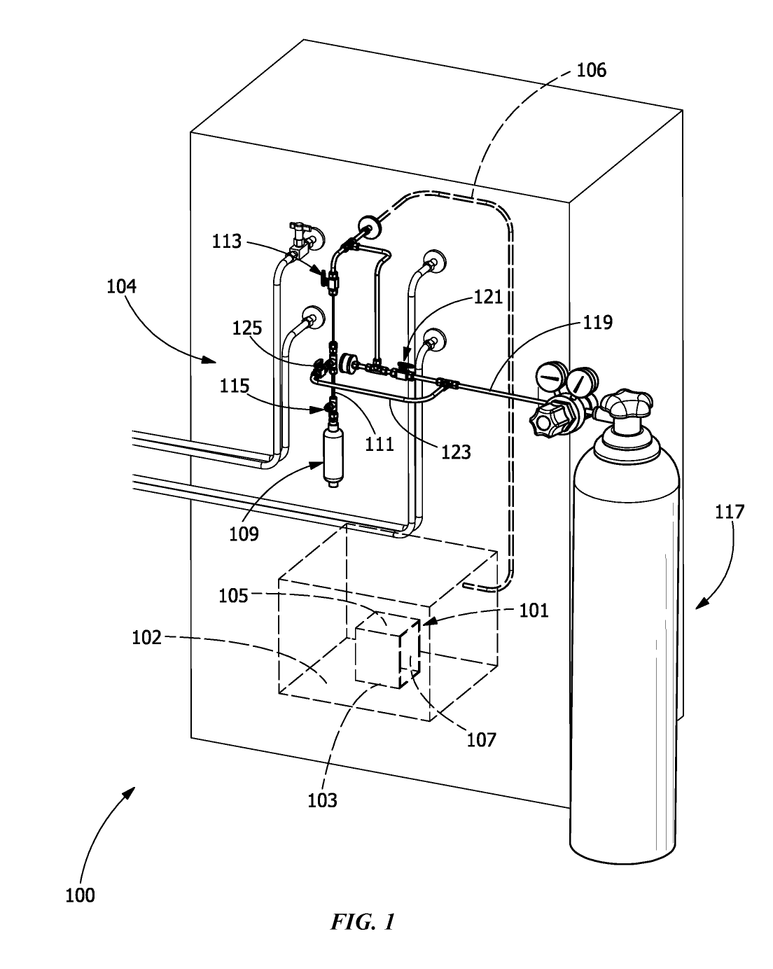

Referring to FIG. 1, a static thermal treatment system 100 includes an enclosed chamber 102 and a liquid handling system 104 in selective fluid communication with the enclosed chamber 102. The static thermal treatment system 100 is configured to produce a material and/or surface treatment on an external surface(s) 105 and/or an internal surface(s) 107, such as, on a metal or metallic substrate(s) 103 of an article, thereby producing a treated article 101. The treated article 101 is produced within the enclosed chamber 102 in response thermal energy being applied to a gaseous precursor.

The static thermal treatment system 100 is capable of converting a liquid precursor flowing through the liquid handling system 104 to the gaseous precursor within the enclosed chamber 102. The static thermal treatment process includes using the static thermal treatment system 100 to produce the treated article 101. In one embodiment, the static thermal treatment process includes providing the enclosed chamber 102, providing the liquid handling system 104, converting the liquid precursor flowing through the liquid handling system 104 to the gaseous precursor within the enclosed chamber 102, and producing the material on the surface of the article in response to the thermal energy being applied to the gaseous precursor within the enclosed chamber 102.

The liquid handling system 104 has any suitable configuration capable of providing the liquid precursor to the enclosed chamber 102 and/or capable of converting the liquid precursor to the gaseous precursor. In one embodiment, the liquid handling system 104 includes a dip tube arrangement 109, with a transport line 111 (for example, 1/16 inch in diameter) extending from the dip tube arrangement 109 toward the enclosed chamber 102, for example, through a flexible hose 106. The transport line 111 is selectively in fluid communication with the enclosed chamber 102 due to a liquid-precursor-controlling valve 113.

The dip tube arrangement 109 includes a septum 115 to permit introduction of the liquid precursor into the dip tube arrangement 109, with the transport line 111 being positioned to urge the liquid precursor into the enclosed chamber 102, for example, through pressure applied from a source, such as, a nitrogen source 117. The liquid precursor travels in a direction opposite or substantially opposite the direction of gravity and/or in a coaxial direction that is perpendicular or substantially perpendicular to the direction of gravity prior to entering the flexible hose 106. In a further embodiment, the liquid precursor and/or the gaseous precursor flow through the flexible hose 106 in the coaxial direction and/or in a direction corresponding with or substantially corresponding with the direction of gravity.

In one embodiment, the nitrogen source 117 selectively applies nitrogen through a source tube 119 (for example, ¼ inch in diameter) to the dip tube arrangement 109 controllable by a nitrogen-controlling valve 121 and a bypass configuration 123 with a bypass valve 125. The nitrogen-controlling valve 121, the bypass configuration 123, and the bypass valve 125 permit flushing of the dip tube arrangement 109 and/or the liquid handling system 104, as well as, carrying of the liquid precursor to the enclosed chamber 102.

In one embodiment, the liquid handling system 104 provides the liquid precursor to the enclosed chamber 102 in the direction of gravity, substantially in the direction of gravity, generally in the direction of gravity, or by any other suitable technique relying primarily upon gravity. For example, in such an embodiment, the liquid handling system 104 may resemble the configuration of an intravenous-drip used in the medical industry.

In one embodiment, the liquid precursor is positioned directly within the enclosed chamber 102, for example, to be released passively or through a time-released configuration.

Other suitable components/features of the liquid handling system 104 include, but are not limited to, a purge system capable of selectively flowing an inert fluid (for example, the nitrogen) through a flowpath (for example, the transport line 111), a multiport valve (for example, a four-port, six-port, eight-port, or ten-port valve) capable of switching from an injection position to a vent/waste/purge position (such as, a valve capable of being used in conjunction with chromatographic columns), a batch processing configuration having one or more flow controllers (such as, with one or more gas mass flow controllers, liquid flow controllers, and an injection line having a coaxial orientation after the controller(s), with the response time from the controller(s) to initiate or halt the flow within the injection line capable of being as brief as 50 ms and/or a bifurcated valve permitting line purging after each use), a stainless steel flow path (such as, a fully-welded construction of a stainless steel flow path, atomization and heat exchanger technologies, for example, ranging from 200 Watts to 5,000 Watts), a carrier gas configuration for contactless vaporization (such as, using a vaporizer having an external liquid flow measurement system and a carrier gas configuration for contactless vaporization, a measurement system with a coaxial liquid injection line or a feed line to a vaporizer, for example, configured to operate using a pressure dispense method), an ultrasonic atomizing nozzle (for example, having an arrangement or piezoelectric transducers to convert electrical input into mechanical energy), or a combination thereof.

In one embodiment, the surface treatment has fluorine, silicon, and carbon and is capable of withstanding temperatures of at least 100° C. (for example, greater than 200° C., greater than 300° C., greater than 400° C., greater than 500° C., greater than 600° C., or any suitable combination, sub-combination, range, or sub-range therein). The surface treatment imparts molecules with carbon-fluorine bonds and silicon-oxygen bonds detectable through infrared spectroscopy.

The surface treatment is detectable through contact angle measurement and/or thermal oxidation measurement. For example, in one embodiment, prior to thermal oxidation, the surface treatment has a water contact angle within the range of between 115° and 170°, such as, between 115° and 140°, between 118° and 135°, between 120° and 121° (for example, on 304 stainless steel), between 125° and 126° (for example, on 316 stainless steel), or any suitable combination, sub-combination, range, or sub-range therein. Additionally or alternatively, in one embodiment, prior to thermal oxidation, the surface treatment has a hexadecane contact angle within the range of between 65° and 110°, such as, between 65° and 90°, between 70° and 85°, between 77° and 78° (for example, on 304 stainless steel), between 75° and 76° (for example, on 316 stainless steel), or any suitable combination, sub-combination, range, or sub-range therein.

The surface treatment is detectable based upon thermal oxidation properties, for example, at 300° C. in air (or another 70% to 75% oxygen environment). In one embodiment, the contact angle of the surface treatment under such thermal oxidation increases for a period of at least 1 hour of thermal oxidation, a period of at least 2 hours of thermal oxidation, or any suitable combination, sub-combination, range, or sub-range therein. In further embodiments, the contact angle under such thermal oxidation stays within a range over a period of at least 3 hours, at least 4 hours, or up to 70 hours. Such ranges include, but are not limited to, between 77° and 81° (for example, a hexadecane contact angle on 304 stainless steel), between 75° and 85° (for example, a hexadecane contact angle on 316 stainless steel), 120° and 133° (for example, a water contact angle on 304 stainless steel), 125° and 135° (for example, a water contact angle on 316 stainless steel), or any suitable combination, sub-combination, range, or sub-range therein.

The surface treatment is imparted by introduction of a fluorine-silicon-carbon-containing precursor within a pressure range and a temperature range for a duration of time during one or more steps in the enclosed chamber 102 and/or vessel. Use of the term “enclosed” is intended to encompass static techniques and differentiate from constant flow techniques, such as, plasma enhanced chemical vapor deposition. Suitable dimensions for the enclosed chamber 102 and/or the vessel include, but are not limited to, having a minimum width of greater than 5 cm, greater than 10 cm, greater than 20 cm, greater than 30 cm, greater than 100 cm, greater than 300 cm, greater than 1,000 cm, between 10 cm and 100 cm, between 100 cm and 300 cm, between 100 cm and 1,000 cm, between 300 cm and 1,000 cm, any other minimum width capable of uniform or substantially uniform heating, or any suitable combination, sub-combination, range, or sub-range therein. In some embodiments, much larger dimensions are present, for example, on the order of meters.

Suitable volumes for the enclosed chamber 102 and/or the vessel include, but are not limited to, greater than 1,000 cm³, greater than 3,000 cm³, greater than 5,000 cm³, greater than 10,000 cm³, greater than 20,000 cm³, between 3,000 cm³ and 5,000 cm³, between 5,000 cm³ and 10,000 cm³, between 5,000 cm³ and 20,000 cm³, between 10,000 cm³ and 20,000 cm³, any other volumes capable of uniform or substantially uniform heating, or any suitable combination, sub-combination, range, or sub-range therein. In some embodiments, much larger dimensions are present, for example, on the order of cubic meters.

The introducing of the fluorine-silicon-carbon-containing precursor within the pressure range and the temperature range for the duration of time during the one or more steps results in constituents of the fluorine-silicon-carbon-containing precursor (for example, the fluorine, the silicon, and the carbon) being within the metal or metallic substrate 103 on and/or within the external surface 105 and/or the internal surface 107. Suitable fluorine-silicon-carbon-containing precursors for imparting the constituents include, but are not limited to, an organofluorotrialkoxysilane, an organofluorosilylhydride, an organofluoro silyl, a fluorinated alkoxysilane, a fluoroalkylsilane, a fluorosilane, or a combination thereof. Additionally or alternatively, specific embodiments of the fluorine-silicon-carbon-containing precursors for imparting the constituents include, but are not limited to, tridecafluoro 1,1,2,2-tetrahydrooctylsilane; (tridecafluoro-1,1,2,2-tetrahydrooctyl) triethoxysilane (also known as triethoxy (1H,1H,2H,2H-perfluoro-1-octyl) silane, triethoxy (3,3,4,4,5,5,6,6,7,7,8,8,8-tridecafluoro-1-octyl) silane, 1H,1H,2H,2H-perfluorooctyltriethoxysilane, or silane, triethoxy (3,3,4,4,5,5,6,6,7,7,8,8,8-tridecafluorooctyl)-); (perfluorohexylethyl) triethoxysilane; silane, (3,3,4,4,5,5,6,6,7,7,8,8,9,9,10,10,10-heptadecafluorodecyl) trimethoxy-; 1H,1H,2H,2H-perfluorodecyl trichlorosilane; 1H,1H,1H,2H-perfluorodecyl trimethoxysilane; 1H,1H,2H,2H-perfluorodecyltriethoxysilane; 1H,1H,2H,2H-perfluorooctyltrimethoxysilane; or a combination thereof.

In one embodiment, the pressure range for the introducing of the fluorine-silicon-carbon-containing precursor is between 0.01 psia and 200 psia, between 1.0 psia and 100 psia, between 5 psia and 40 psia, between 20 psia and 25 psia, greater than 25 psia, greater than 20 psia, less than 20 psia, less than 15 psia, 1.0 psia, 5 psia, 20 psia, 23 psia, 25 psia, 40 psia, 100 psia, 200 psia, or any suitable combination, sub-combination, range, or sub-range therein.

In one embodiment, the temperature range for the introducing of the fluorine-silicon-carbon-containing precursor is between 100° C. and 700° C., between 100° C. and 450° C., between 100° C. and 300° C., between 200° C. and 500° C., between 300° C. and 600° C., between 450° C. and 700° C., 700° C., 450° C., 100° C., between 200° C. and 600° C., between 300° C. and 600° C., between 400° C. and 500° C., 300° C., 400° C., 500° C., 600° C., or any suitable combination, sub-combination, range, or sub-range thereof.

In one embodiment, the duration of time for the introducing of the fluorine-silicon-carbon-containing precursor is at least 10 minutes, at least 1 hour, at least 2 hours, at least 3 hours, at least 4 hours, at least 5 hours, at least 7 hours, at least 10 hours, between 10 minutes and 24 hours, between 1 hour and 10 hours, between 1 hour and 5 hours, between 1 hour and 4 hours, between 2 hours and 10 hours, between 4 hours and 6 hours, between 4 hours and 8 hours, between 4 hours and 10 hours, between 6 hours and 8 hours, less than 10 hours, less than 8 hours, less than 6 hours, less than 4 hours, or any suitable combination, sub-combination, range, or sub-range therein.

The one or more steps of introducing of the fluorine-silicon-carbon-containing precursor includes one cycle, two cycles, three cycles, four cycles, or more than four cycles preceded by or followed by other steps, such as, heating steps and/or oxidation steps that are concurrent or sequential. For example, in one embodiment, the surface treatment includes an oxidation step prior to the introducing of the fluorine-silicon-carbon-containing precursor. The oxidation step(s) includes exposure to any suitable chemical species capable of donating a reactive oxygen species into the coating under predetermined oxidation conditions.

The oxidation step is capable of being achieved by exposure to water (alone, with zero air, or with an inert gas), oxygen (for example, at a concentration, by weight, of at least 50%), air (for example, alone, not alone, and/or as zero air), nitrous oxide, ozone, peroxide, or a combination thereof. As used herein, the term “zero air” refers to atmospheric air having less than 0.1 ppm total hydrocarbons. The term “air” generally refers to a gaseous fluid, by weight, of mostly nitrogen, with the oxygen being the second highest concentration species within. For example, in one embodiment, the nitrogen in the oxidation step is present at a concentration, by weight, of at least 70% (for example, between 75% and 76%) and oxygen is present at a concentration, by weight, of at least 20% (for example, between 23% and 24%).

In one embodiment, the oxidation step is with water as an oxidizing agent (for example, within a temperature range of between 25° C. and 600° C., a temperature range of between 300° C. and 600° C., or at a temperature of 450° C.). In one embodiment, the oxidation step is with air and water (for example, within a temperature range of between 100° C. and 600° C., a temperature range of 300° C. to 600° C., or at a temperature of 450° C.). In one embodiment, the oxidation step is only with air (for example, within a temperature range of between 100° C. and 600° C., a temperature range of between 300° C. and 600° C., or at a temperature of 450° C.). In one embodiment, the oxidation step is with nitrous oxide (N₂O). Specifically, N₂O is applied under heat (for example, about 450° C.) with a pressure of substantially pure N₂O in a vessel with carbosilane-coated samples.

Other suitable steps to precede or follow the introducing of the fluorine-silicon-carbon-containing gas include purging, cleaning, and/or heating the enclosed chamber 102 and/or the vessel. In one embodiment, the purging evacuates or substantially evacuates gas(es) from the enclosed chamber 102 and/or the vessel by selectively applying a purge gas. Suitable purge gases are nitrogen, helium, argon, or any other inert gas. The purging is in one purge cycle, two purge cycles, three purge cycles, more than three purge cycles, or any suitable number of purge cycles that permits the enclosed chamber 102 and/or the vessel to be a chemically inert environment.

In one embodiment, the cleaning removes undesirable materials from the metal or metallic substrate 103. The cleaning includes any suitable technique for removing materials that may volatilize in the higher temperatures of the enclosed chamber 102 and/or vessel or that may inhibit the ability for the surface treatment to impart the fluorine, silicon, and carbon.

In one embodiment, the heating is from a lower temperature of the fluorine-silicon-carbon-containing precursor to a higher temperature of the fluorine-silicon-carbon-containing precursor. Depending upon the species of the fluorine-silicon-carbon-containing precursor utilized, suitable temperatures include, but are not limited to, less than 30° C., less than 60° C., less than 100° C., less than 150° C., less than 200° C., less than 250° C., less than 300° C., less than 350° C., less than 400° C., less than 440° C., less than 450° C., between 100° C. and 300° C., between 125° C. and 275° C., between 200° C. and 300° C., between 230° C. and 270° C., or any suitable combination, sub-combination, range, or sub-range therein.

The metal or metallic substrate 103 is any suitable metal or metallic alloy capable of receiving the surface treatment. Suitable metal or metallic substrates 103 include, but are not limited to, ferrous-based alloys, nickel-based alloys, stainless steels (martensitic or austenitic), aluminum alloys, and/or composite metals. Prior to the treatment, the metal or metallic substrate 103 is devoid or substantially devoid of fluorine.

In one embodiment, the metal or metallic substrate 103 is or includes a composition, by weight, of up to 0.08% carbon, between 18% and 20% chromium, up to 2% manganese, between 8% and 10.5% nickel, up to 0.045% phosphorus, up to 0.03% sulfur, up to 1% silicon, and a balance of iron (for example, between 66% and 74% iron).

In one embodiment, the metal or metallic substrate 103 is or includes a composition, by weight, of up to 0.08% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron.

In one embodiment, the metal or metallic substrate 103 is or includes a composition, by weight, of up to 0.03% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron.

In one embodiment, the metal or metallic substrate 103 is or includes a composition, by weight, of between 14% and 17% chromium, between 6% and 10% iron, between 0.5% and 1.5% manganese, between 0.1% and 1% copper, between 0.1% and 1% silicon, between 0.01% and 0.2% carbon, between 0.001% and 0.2% sulfur, and a balance nickel (for example, 72%).

In one embodiment, the metal or metallic substrate 103 is or includes a composition, by weight, of between 20% and 24% chromium, between 1% and 5% iron, between 8% and 10% molybdenum, between 10% and 15% cobalt, between 0.1% and 1% manganese, between 0.1% and 1% copper, between 0.8% and 1.5% aluminum, between 0.1% and 1% titanium, between 0.1% and 1% silicon, between 0.01% and 0.2% carbon, between 0.001% and 0.2% sulfur, between 0.001% and 0.2% phosphorus, between 0.001% and 0.2% boron, and a balance nickel (for example, between 44.2% and 56%).

In one embodiment, the metal or metallic substrate 103 is or includes a composition, by weight, of between 20% and 23% chromium, between 4% and 6% iron, between 8% and 10% molybdenum, between 3% and 4.5% niobium, between 0.5% and 1.5% cobalt, between 0.1% and 1% manganese, between 0.1% and 1% aluminum, between 0.1% and 1% titanium, between 0.1% and 1% silicon, between 0.01% and 0.5% carbon, between 0.001% and 0.02% sulfur, between 0.001% and 0.02% phosphorus, and a balance nickel (for example, 58%).

In one embodiment, the metal or metallic substrate 103 is or includes a composition, by weight, of between 25% and 35% chromium, between 8% and 10% iron, between 0.2% and 0.5% manganese, between 0.005% and 0.02% copper, between 0.01% and 0.03% aluminum, between 0.3% and 0.4% silicon, between 0.005% and 0.03% carbon, between 0.001% and 0.005% sulfur, and a balance nickel (for example, 59.5%).

In one embodiment, the metal or metallic substrate 103 is or includes a composition, by weight, of between 17% and 21%, between 2.8% and 3.3%, between 4.75% and 5.5% niobium, between 0.5% and 1.5% cobalt, between 0.1% and 0.5% manganese, between 0.2% and 0.8% copper, between 0.65% and 1.15% aluminum, between 0.2% and 0.4% titanium, between 0.3% and 0.4% silicon, between 0.01% and 1% carbon, between 0.001 and 0.02% sulfur, between 0.001 and 0.02% phosphorus, between 0.001 and 0.02% boron, and a balance nickel (for example, between 50% and 55%).

In one embodiment, the metal or metallic substrate 103 is or includes a composition, by weight, of between 2% and 3% cobalt, between 15% and 17% chromium, between 5% and 17% molybdenum, between 3% and 5% tungsten, between 4% and 6% iron, between 0.5% and 1% silicon, between 0.5% and 1.5% manganese, between 0.005 and 0.02% carbon, between 0.3% and 0.4% vanadium, and a balance nickel.

In one embodiment, the metal or metallic substrate 103 is or includes a composition, by weight, of up to 0.15% carbon, between 3.5% and 5.5% tungsten, between 4.5% and 7% iron, between 15.5% and 17.5% chromium, between 16% and 18% molybdenum, between 0.2% and 0.4% vanadium, up to 1% manganese, up to 1% sulfur, up to 1% silicon, up to 0.04% phosphorus, up to 0.03% sulfur, and a balance nickel.

In one embodiment, the metal or metallic substrate 103 is or includes a composition, by weight, of up to 2.5% cobalt, up to 22% chromium, up to 13% molybdenum, up to 3% tungsten, up to 3% iron, up to 0.08% silicon, up to 0.5% manganese, up to 0.01% carbon, up to 0.35% vanadium, and a balance nickel (for example, 56%).

In one embodiment, the metal or metallic substrate 103 is or includes a composition, by weight, of between 1% and 2% cobalt, between 20% and 22% chromium, between 8% and 10% molybdenum, between 0.1% and 1% tungsten, between 17% and 20% iron, between 0.1% and 1% silicon, between 0.1% and 1% manganese, between 0.05 and 0.2% carbon, and a balance nickel.

In one embodiment, the metal or metallic substrate 103 is or includes a composition, by weight, of between 0.01% and 0.05% boron, between 0.01% and 0.1% chromium, between 0.003% and 0.35% copper, between 0.005% and 0.03% gallium, between 0.006% and 0.8% iron, between 0.006% and 0.3% magnesium, between 0.02% and 1% silicon+iron, between 0.006% and 0.35% silicon, between 0.002% and 0.2% titanium, between 0.01% and 0.03% vanadium+titanium, between 0.005% and 0.05% vanadium, between 0.006% and 0.1% zinc, and a balance aluminum (for example, greater than 99%).

In one embodiment, the metal or metallic substrate 103 is or includes a composition, by weight, of between 0.05% and 0.4% chromium, between 0.03% and 0.9% coper, between 0.05% and 1% iron, between 0.05% and 1.5% magnesium, between 0.5% and 1.8% manganese, between 0.5% and 0.1% nickel, between 0.03% and 0.35% titanium, up to 0.5% vanadium, between 0.04% and 1.3% zinc, and a balance aluminum (for example, between 94.3% and 99.8%).

In one embodiment, the metal or metallic substrate 103 is or includes a composition, by weight, of between 0.0003% and 0.07% beryllium, between 0.02% and 2% bismuth, between 0.01% and 0.25% chromium, between 0.03% and 5% copper, between 0.09% and 5.4% iron, between 0.01% and 2% magnesium, between 0.03% and 1.5% manganese, between 0.15% and 2.2% nickel, between 0.6% and 21.5% silicon, between 0.005% and 0.2% titanium, between 0.05% and 10.7% zinc, and a balance aluminum (for example, between 70.7% to 98.7%).

In one embodiment, the metal or metallic substrate 103 is or includes a composition, by weight, of between 0.15% and 1.5% bismuth, between 0.003% and 0.06% boron, between 0.03% and 0.4% chromium, between 0.01% and 1.2% copper, between 0.12% and 0.5% chromium+manganese, between 0.04% and 1% iron, between 0.003% and 2% lead, between 0.2% and 3% magnesium, between 0.02% and 1.4% manganese, between 0.05% and 0.2% nickel, between 0.5% and 0.5% oxygen, between 0.2% and 1.8% silicon, up to 0.05% strontium, between 0.05% and 2% tin, between 0.01% and 0.25% titanium, between 0.05% and 0.3% vanadium, between 0.03% and 2.4% zinc, between 0.05% and 0.2% zirconium, between 0.150 and 0.2% zirconium+titanium, and a balance of aluminum (for example, between 91.7% and 99.6%).

In one embodiment, the metal or metallic substrate 103 is or includes a composition, by weight, of between 0.4% and 0.8% silicon, up to 0.7% iron, between 0.15% and 0.4% copper, up to 0.15% manganese, between 0.8% and 1.2% magnesium, between 0.04% and 0.35% chromium, up to 0.25% zinc, up to 0.15% titanium, optional incidental impurities (for example, at less than 0.05% each, totaling less that 0.15%), and a balance of aluminum (for example, between 95% and 98.6%).

In one embodiment, the metal or metallic substrate 103 is or includes a composition, by weight, of between 11% and 13% silicon, up to 0.6% impurities/residuals, and a balance of aluminum.

The treated article 101 having the metal or metallic substrate 103 with the surface treatment (for example, on and/or within the external surface 105 and/or the internal surface 107 of the metal or metallic substrate 103) is capable of having a geometry and/or structure, such as, but not limited to, being tubular, being planar, being non-planar, being of complex geometry, being angled, being straight, being bent, being coiled, being layered, being interwoven, being stacked, being rigid, being flexible, being drilled, being cut, being etched, being sintered, being ground, being polished (mechanically or electrochemically), being cast, being forged, being molded, being additively produced, being tempered, being non-tempered, having equiaxed grain structure, having directionally-solidified or columnar grain structure, having single crystal grain structure, having a single material, having multiple materials (for example, by being joined or welded), or a suitable combination thereof.

In some embodiments, the treated article 101 is one or more of fittings (for example, unions, connectors, adaptors, other connections between two or more pieces of tubing, for example, capable of making a leak-free or substantially leak-free seal), compression fittings (including ferrules, such as, a front and back ferrule), tubing (for example, coiled tubing, tubing sections such as used to connect a sampling apparatus, pre-bent tubing, straight tubing, loose wound tubing, tightly bound tubing, and/or flexible tubing), valves (such as, gas sampling, liquid sampling, transfer, shut-off, or check valves, for example, including a rupture disc, stem, poppet, rotor, multi-position configuration, able to handle vacuum or pressure, a handle or stem for a knob, ball-stem features, ball valve features, check valve features, springs, multiple bodies, seals, needle valve features, packing washers, and/or stems), quick-connects, sample cylinders, regulators and/or flow-controllers (for example, including o-rings, seals, and/or diaphragms), injection ports (for example, for gas chromatographs), in-line filters (for example, having springs, sintered metal filters, mesh screens, and/or weldments), glass liners, gas chromatograph components, liquid chromatography components, components associated with vacuum systems and chambers, components associated with analytical systems, sample probes, control probes, downhole sampling containers, drilled and/or machined block components, manifolds, or a combination thereof.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified. All compositions shall be understood as potentially having incidental impurities, for example, that do not affect performance of such compositions.

What is claimed is:

1. A static thermal treatment process, comprising:
providing an enclosed chamber configured to produce a material on a surface of an article within the enclosed chamber in response thermal energy being applied to a gaseous precursor;
providing a liquid handling system in selective fluid communication with the enclosed chamber;
flowing a liquid precursor through the liquid handling system;
converting the liquid precursor to the gaseous precursor; and
producing the material on the surface of the article in response to the thermal energy being applied to the gaseous precursor within the enclosed chamber.

2. The static thermal treatment process of claim 1, wherein the liquid handling system includes a purge system capable of selectively flowing an inert fluid through a flowpath of the liquid precursor.

3. The static thermal treatment process of claim 1, wherein the liquid handling system urges the liquid precursor in a direction substantially opposite the direction of gravity.

4. The static thermal treatment process of claim 1, wherein the liquid handling system includes a multiport valve.

5. The static thermal treatment process of claim 1, wherein the liquid handling system a batch processing configuration having one or more flow controllers.

6. The static thermal treatment process of claim 1, wherein the liquid handling system includes a stainless steel flow path.

7. The static thermal treatment process of claim 1, wherein the liquid handling system includes a carrier gas configuration for contactless vaporization.

8. The static thermal treatment process of claim 1, wherein the liquid handling system includes a vaporizer.

9. The static thermal treatment process of claim 1, wherein the liquid handling system includes an ultrasonic atomizing nozzle.

10. The static thermal treatment process of claim 1, wherein the producing is a deposition of the material through chemical vapor deposition.

11. The static thermal treatment process of claim 1, wherein the producing is a reaction of the surface.

12. The static thermal treatment process of claim 1, wherein the liquid precursor includes fluorine, silicon, and carbon.

13. The static thermal treatment process of claim 1, wherein the liquid precursor is or includes an organofluorotrialkoxysilane, an organofluorosilylhydride, an organofluoro silyl, a fluorinated alkoxysilane, a fluoroalkylsilane, a fluorosilane, or a combination thereof.

14. The static thermal treatment process of claim 1, wherein the liquid precursor is or includes tridecafluoro 1,1,2,2-tetrahydrooctylsilane; (tridecafluoro-1,1,2,2-tetrahydrooctyl) triethoxysilane; (perfluorohexyl ethyl) triethoxysilane; silane, (3,3,4,4,5,5,6,6,7,7,8,8,9,9,10,10,10-heptadecafluorodecyl) trimethoxy-; 1H,1H,2H,2H-perfluorodecyl trichlorosilane; 1H,1H,1H,2H-perfluorodecyl trimethoxysilane; 1H,1H,2H,2H-perfluorodecyltriethoxysil ane; 1H,1H,2H,2H-perfluorooctyltrimethoxysilane; or a combination thereof.

15. The static thermal treatment process of claim 1, wherein the surface is a stainless steel substrate.

16. The static thermal treatment process of claim 1, wherein the surface is a ferrous-based alloy.

17. The static thermal treatment process of claim 1, wherein the surface is a nickel-based alloy.

18. The static thermal treatment process of claim 1, wherein the surface has a composition, by weight, of:
up to 0.08% carbon, between 18% and 20% chromium, up to 2% manganese, between 8% and 10.5% nickel, up to 0.045% phosphorus, up to 0.03% sulfur, up to 1% silicon, and a balance of iron;
up to 0.08% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron;
up to 0.03% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron;
between 14% and 17% chromium, between 6% and 10% iron, between 0.5% and 1.5% manganese, between 0.1% and 1% copper, between 0.1% and 1% silicon, between 0.01% and 0.2% carbon, between 0.001% and 0.2% sulfur, and a balance nickel;
between 20% and 24% chromium, between 1% and 5% iron, between 8% and 10% molybdenum, between 10% and 15% cobalt, between 0.1% and 1% manganese, between 0.1% and 1% copper, between 0.8% and 1.5% aluminum, between 0.1% and 1% titanium, between 0.1% and 1% silicon, between 0.01% and 0.2% carbon, between 0.001% and 0.2% sulfur, between 0.001% and 0.2% phosphorus, between 0.001% and 0.2% boron, and a balance nickel;
between 20% and 23% chromium, between 4% and 6% iron, between 8% and 10% molybdenum, between 3% and 4.5% niobium, between 0.5% and 1.5% cobalt, between 0.1% and 1% manganese, between 0.1% and 1% aluminum, between 0.1% and 1% titanium, between 0.1% and 1% silicon, between 0.01% and 0.5% carbon, between 0.001% and 0.02% sulfur, between 0.001% and 0.02% phosphorus, and a balance nickel;
between 25% and 35% chromium, between 8% and 10% iron, between 0.2% and 0.5% manganese, between 0.005% and 0.02% copper, between 0.01% and 0.03% aluminum, between 0.3% and 0.4% silicon, between 0.005% and 0.03% carbon, between 0.001% and 0.005% sulfur, and a balance nickel;
between 17% and 21%, between 2.8% and 3.3%, between 4.75% and 5.5% niobium, between 0.5% and 1.5% cobalt, between 0.1% and 0.5% manganese, between 0.2% and 0.8% copper, between 0.65% and 1.15% aluminum, between 0.2% and 0.4% titanium, between 0.3% and 0.4% silicon, between 0.01% and 1% carbon, between 0.001 and 0.02% sulfur, between 0.001 and 0.02% phosphorus, between 0.001 and 0.02% boron, and a balance nickel;
between 2% and 3% cobalt, between 15% and 17% chromium, between 5% and 17% molybdenum, between 3% and 5% tungsten, between 4% and 6% iron, between 0.5% and 1% silicon, between 0.5% and 1.5% manganese, between 0.005 and 0.02% carbon, between 0.3% and 0.4% vanadium, and a balance nickel;
up to 0.15% carbon, between 3.5% and 5.5% tungsten, between 4.5% and 7% iron, between 15.5% and 17.5% chromium, between 16% and 18% molybdenum, between 0.2% and 0.4% vanadium, up to 1% manganese, up to 1% sulfur, up to 1% silicon, up to 0.04% phosphorus, up to 0.03% sulfur, and a balance nickel;
up to 2.5% cobalt, up to 22% chromium, up to 13% molybdenum, up to 3% tungsten, up to 3% iron, up to 0.08% silicon, up to 0.5% manganese, up to 0.01% carbon, up to 0.35% vanadium, and a balance nickel;
between 1% and 2% cobalt, between 20% and 22% chromium, between 8% and 10% molybdenum, between 0.1% and 1% tungsten, between 17% and 20% iron, between 0.1% and 1% silicon, between 0.1% and 1% manganese, between 0.05 and 0.2% carbon, and a balance nickel;
between 0.01% and 0.05% boron, between 0.01% and 0.1% chromium, between 0.003% and 0.35% copper, between 0.005% and 0.03% gallium, between 0.006% and 0.8% iron, between 0.006% and 0.3% magnesium, between 0.02% and 1% silicon+iron, between 0.006% and 0.35% silicon, between 0.002% and 0.2% titanium, between 0.01% and 0.03% vanadium+titanium, between 0.005% and 0.05% vanadium, between 0.006% and 0.1% zinc, and a balance aluminum;
between 0.05% and 0.4% chromium, between 0.03% and 0.9% coper, between 0.05% and 1% iron, between 0.05% and 1.5% magnesium, between 0.5% and 1.8% manganese, between 0.5% and 0.1% nickel, between 0.03% and 0.35% titanium, up to 0.5% vanadium, between 0.04% and 1.3% zinc, and a balance aluminum;
between 0.0003% and 0.07% beryllium, between 0.02% and 2% bismuth, between 0.01% and 0.25% chromium, between 0.03% and 5% copper, between 0.09% and 5.4% iron, between 0.01% and 2% magnesium, between 0.03% and 1.5% manganese, between 0.15% and 2.2% nickel, between 0.6% and 21.5% silicon, between 0.005% and 0.2% titanium, between 0.05% and 10.7% zinc, and a balance aluminum;
between 0.15% and 1.5% bismuth, between 0.003% and 0.06% boron, between 0.03% and 0.4% chromium, between 0.01% and 1.2% copper, between 0.12% and 0.5% chromium+manganese, between 0.04% and 1% iron, between 0.003% and 2% lead, between 0.2% and 3% magnesium, between 0.02% and 1.4% manganese, between 0.05% and 0.2% nickel, between 0.5% and 0.5% oxygen, between 0.2% and 1.8% silicon, up to 0.05% strontium, between 0.05% and 2% tin, between 0.01% and 0.25% titanium, between 0.05% and 0.3% vanadium, between 0.03% and 2.4% zinc, between 0.05% and 0.2% zirconium, between 0.150 and 0.2% zirconium+titanium, and a balance of aluminum;
between 0.4% and 0.8% silicon, up to 0.7% iron, between 0.15% and 0.4% copper, up to 0.15% manganese, between 0.8% and 1.2% magnesium, between 0.04% and 0.35% chromium, up to 0.25% zinc, up to 0.15% titanium, optional incidental impurities, and a balance of aluminum; or between 11% and 13% silicon, up to 0.6% impurities, and a balance of aluminum.

19. A static thermal treatment system, comprising:
an enclosed chamber configured to produce a material on a surface of an article within the enclosed chamber in response to thermal energy being applied to a gaseous precursor;
a liquid handling system in selective fluid communication with the enclosed chamber;
wherein the static thermal treatment system is capable of converting a liquid precursor flowing through the liquid handling system to the gaseous precursor within the chamber; and
wherein the static thermal treatment system is capable of producing the material on the surface of the article in response to the thermal energy being applied to the gaseous precursor within the enclosed chamber.

20. A static thermal treatment process, comprising:
providing an enclosed chamber configured to produce a material on a metal or metallic surface of an article within the enclosed chamber in response thermal energy being applied to a gaseous precursor;
converting a fluorine-containing liquid precursor to the gaseous precursor; and
producing the material on the metal or metallic surface of the article in response to the thermal energy being applied to the gaseous precursor within the enclosed chamber.
